(19) United States
(12) Patent Application Publication
(10) Pub. No.: US 2012/0191393 A1
(43) Pub. Date: Jul. 26, 2012

(54) FREQUENCY DETERMINING CIRCUIT AND SEMICONDUCTOR DEVICE

(75) Inventors: Hironori SATOU, Ome (JP); Takeshi ISEZAKI, Odawara (JP); Tomofumi HOKARI, Akishima (JP)

(73) Assignee: HITACHI, LTD.

(21) Appl. No.: 13/357,983

(22) Filed: Jan. 25, 2012

(30) Foreign Application Priority Data
Jan. 25, 2011 (JP) JP2011-012743

(51) Int. Cl. G06F 19/00; G01R 23/10

(52) U.S. Cl. 702/78

(57) ABSTRACT

A technique capable of determining a frequency of a data signal having a mixture of short and long pulse widths is provided. In a frequency determining circuit for determining a frequency from different data signals having a plurality of frequencies, the frequency determining circuit includes a circuit which acquires the different data signals having the plurality of frequencies and determines the frequency based on the number of counts of the signal having the pulse width shorter than the predetermined pulse width. For example, the signal having the pulse width shorter than the predetermined pulse width is detected, and the number of pulses of the detected signal is counted. By previously making correspondence of the frequency with the number of counts of the pulse, the frequency can be determined based on the number of counts.

### CROSS-REFERENCE TO RELATED APPLICATION

The present application claims priority from Japanese Patent Application No. 2011-012743 filed on Jan. 25, 2011, the content of which is hereby incorporated by reference into this application.

### TECHNICAL FIELD OF THE INVENTION

The present invention relates to a technique of a frequency determining circuit. More particularly, the present invention relates to a technique effectively applied to a frequency determining circuit for determining a frequency from a plurality of data signals having different frequencies and to a semiconductor device including this frequency determining circuit.

### BACKGROUND OF THE INVENTION

For example, a data rate for transferring data between transmitting/receiving LSIs has increased as increase in a speed of an IT device in recent years, and deterioration of the transmitted signal has occurred due to a transmission channel. Therefore, the long-distance high-speed transmission has been difficult. Against such a problem, by inserting an LSI having a waveform shaping function such as a backplane signal conditioner between the transmitting/receiving LSIs, the long-distance high-speed transmission can be achieved. Since the LSI inserted between the transmitting/receiving LSIs is operated at a plurality of transfer rates, a technique of determining a frequency is required.

For example, Japanese Patent Application Laid-Open Publication No. 2009-76965 (Patent Document 1) describes a technique of discriminating a frequency of an input clock signal having any one of a plurality of predetermined frequencies against a problem that a sampling frequency of an input signal cannot be discriminated.

### SUMMARY OF THE INVENTION

In a conventional technique of determining the frequency including the technique of Patent Document 1 as described above and others, when the frequency is specified from different data signals having a plurality of frequencies, it is difficult to determine the frequency even if a pulse number of each data signal is counted. This is because a counted pulse width is not always shorter than a predetermined pulse width since a pattern of the data signal is not constant and has a mixture of short and long pulse widths. Therefore, it is required to count only the pulse width shorter than the predetermined pulse width from the data signals having the mixture of short and long pulse widths.

Accordingly, the present invention has been made in consideration of the above-described problems, and a main preferred aim thereof is to provide a technique capable of determining a frequency of a data signal having a mixture of short and long pulse widths.

The above and other preferred aims and novel characteristics of the present invention will be apparent from the description of the present specification and the accompanying drawings.

The typical ones of the inventions disclosed in the present application will be briefly described as follows.

That is, in a frequency determining circuit for determining a frequency from different data signals having a plurality of frequencies, the frequency determining circuit has a feature that the different data signals having the plurality of frequencies are acquired to determine the frequency based on the number of counts of the signal having the pulse width shorter than the predetermined pulse width.

More specifically, the frequency determining circuit includes: a data-rate detecting circuit for detecting the signal having the pulse width shorter than the predetermined pulse width; a counter circuit for counting a signal detected by this data-rate detecting circuit; a timer circuit for controlling a section where the frequency is determined; and a controlling circuit for determining the frequency from the number of counts counted by the counter circuit, based on a relation between the frequency and the number of counts which is previously corresponded thereto.

Also, the present invention can be also applied to a semiconductor device including the frequency determining circuit having the feature as described above.

The effects obtained by typical aspects of the present invention will be briefly described below.

That is, the frequency of the data signal having the mixture of short and long pulse widths can be determined.

### BRIEF DESCRIPTIONS OF THE DRAWINGS

FIG. 1 is a diagram showing one configuration example of a data-transfer system including a plurality of integrated circuits performing the data transfer, according to a first embodiment of the present invention;

FIG. 2 is a block diagram showing one configuration example of a transmission mechanism performing the data transfer of the data-transfer integrated circuit, according to the first embodiment of the present invention;

FIG. 3 is a block diagram showing one configuration example of a frequency determining circuit according to the first embodiment of the present invention;

FIG. 4 is a circuit diagram showing one configuration example of a data-rate detecting circuit according to the first embodiment of the present invention;

FIG. 5 is a signal waveform diagram for explaining one operation example of the data-rate detecting circuit according to the first embodiment of the present invention;

FIG. 6 is a signal waveform diagram for explaining one operation example (in a case of a clock signal of 4.0 GHz and a data signal of 2.5 GHz) of the data-rate detecting circuit according to the first embodiment of the present invention;

FIG. 7 is a signal waveform diagram for explaining one operation example (in a case of a clock signal of 4.0 GHz and a data signal of 8.0 GHz) of the data-rate detecting circuit according to the first embodiment of the present invention;

FIG. 8 is a circuit diagram showing one configuration example of a part of a data-rate detecting circuit according to a second embodiment of the present invention;

FIG. 9 is a signal waveform diagram for explaining one operation example (in a case without a delay circuit) of the part of the data-rate detecting circuit for comparison according to the second embodiment of the present invention;

FIG. 10 is a signal waveform diagram for explaining one operation example (in a case with the delay circuit) of the part of the data-rate detecting circuit according to the second embodiment of the present invention;

FIG. 11 is a circuit diagram showing a modified configuration example of the part of the data-rate detecting circuit according to the second embodiment of the present invention;

FIG. 12 is a block diagram showing one configuration example of a transmission mechanism performing data transfer of a data-transfer integrated circuit according to a third embodiment of the present invention;

FIG. 13 is a block diagram showing one configuration example of a transmission mechanism performing data transfer of a data-transfer integrated circuit according to a fourth embodiment of the present invention; and

FIG. 14 is a block diagram showing one configuration example of a transmission mechanism performing data transfer of a data-transfer integrated circuit according to a fifth embodiment of the present invention.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference symbols throughout the drawings for describing the embodiments, and the repetitive description thereof will be omitted.

### Summary of Embodiments of the Present Invention

A frequency determining circuit according to embodiments of the present invention is a frequency determining circuit for determining a frequency from different data signals having a plurality of frequencies, and it has a feature that the frequency determining circuit includes a circuit (201) which acquires the different data signals having the plurality of frequencies and determines the frequency based on the number of counts of a signal having a pulse width shorter than a predetermined pulse width.

More specifically, this circuit for determining the frequency includes: a data-rate detecting circuit (301) for detecting the signal having the pulse width shorter than the predetermined pulse width; a counter circuit (302) for counting a signal detected by the data-rate detecting circuit; a timer circuit (303) for controlling a section where the frequency is determined; and a controlling circuit (304) for determining the frequency from the number of counts counted by the counter circuit, based on a relation between the frequency and the number of counts which is previously corresponded thereto.

Each embodiment based on the summary of the embodiments of the present invention described above is specifically explained below. Each embodiment described below is one example using the present invention, and the present invention is not limited by the following embodiments.

### First Embodiment

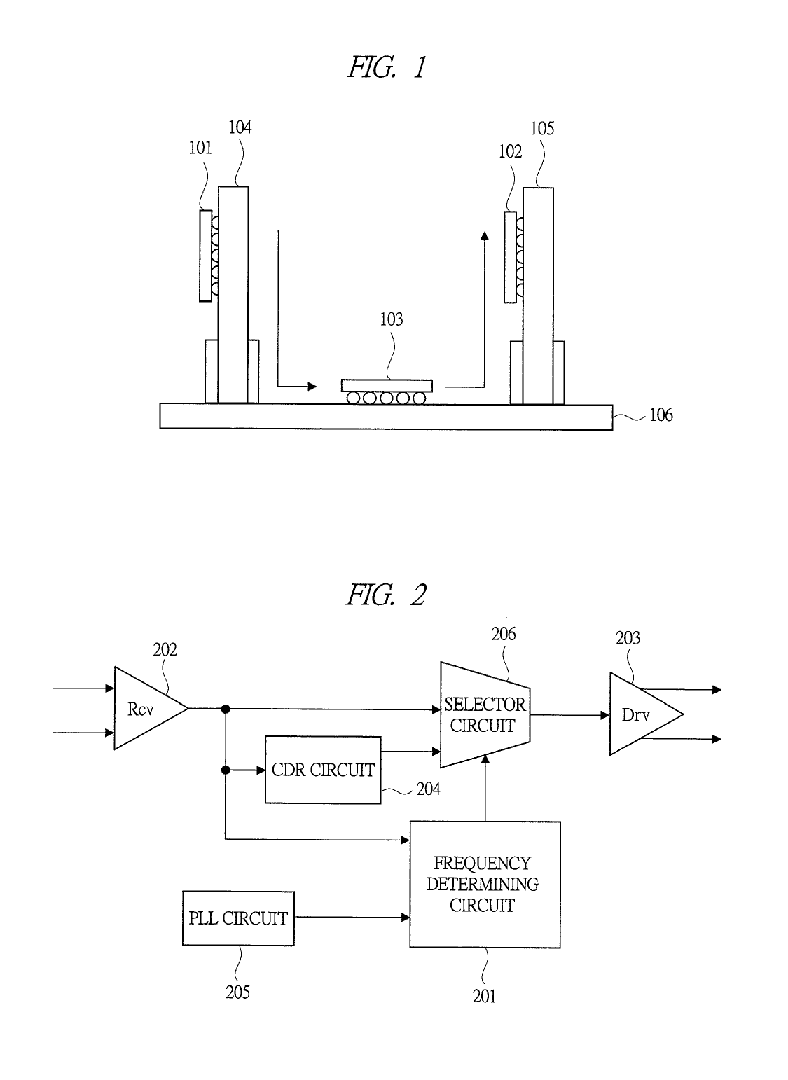

A first embodiment of the present invention is explained with reference to FIGS. 1 to 7.

<Configuration of Data-Transfer System>

First, with reference to FIG. 1, one configuration example of a data-transfer system including a plurality of integrated circuits (semiconductor devices) according to a first embodiment, which perform data transfer, is explained. FIG. 1 is a diagram showing one configuration example of this data-transfer system including the plurality of integrated circuits performing the data transfer.

The data-transfer system shown in FIG. 1 includes: a transmitting-side integrated circuit 101; a board 104 on which this integrated circuit 101 is mounted; a receiving-side integrated circuit 102; a board 105 on which this integrated circuit 102 is mounted; a data-transfer integrated circuit 103; and a motherboard 106 on which this integrated circuit 103 is mounted. The board 104 on which the transmitting-side integrated circuit 101 is mounted and the board 105 on which the receiving-side integrated circuit 102 is mounted are mounted by connector connection on the motherboard 106 on which the data-transfer integrated circuit 103 is mounted.

This data-transfer system is electrically connected from the transmitting-side integrated circuit 101 to the data-transfer integrated circuit 103 via the board 104 and the motherboard 106, and besides, is electrically connected from the data-transfer integrated circuit 103 to the receiving-side integrated circuit 102 via the motherboard 106 and the board 105. FIG. 1 shows an example of the date transfer from the transmitting-side integrated circuit 101 to the receiving-side integrated circuit 102 via the data-transfer integrated circuit 103. The data-transfer integrated circuit 103 includes: a function serving as a repeater of a high-speed transmission channel; and a waveform equalizing circuit, receives a data from the transmitting-side integrated circuit 101, and transfers a waveform-shaped data to the receiving-side integrated circuit 102.

In such a data-transfer system, each of the transmitting-side integrated circuit 101, the receiving-side integrated circuit 102, and the data-transfer integrated circuit 103 is manufactured as, for example, a semiconductor device such as a semiconductor chip obtained by forming each integrated circuit on a semiconductor substrate. In the present invention, among these semiconductor devices, the semiconductor device on which the data-transfer integrated circuit 103 is formed has a feature which is explained in detail below.

<Configuration of Transmission Mechanism Performing Data Transfer of Data-Transfer Integrated Circuit>

Next, with reference to FIG. 2, one configuration example of the transmission mechanism performing the data transfer of the above-described data-transfer integrated circuit 103 is explained. FIG. 2 is a block diagram showing one configuration example of the transmission mechanism performing the data transfer of this data-transfer integrated circuit 103.

The data-transfer integrated circuit 103 shown in FIG. 2 includes: a frequency determining circuit 201; an input circuit (Rcv) 202; an output circuit (Dry) 203; a CDR (Clock Data Recovery) circuit 204; a PLL (Phase Locked Loop) circuit 205; and a selector circuit 206.

The input circuit 202 receives a data from the transmitting-side integrated circuit 101, and outputs the data to the frequency determining circuit 201, the CDR circuit 204, and the selector circuit 206.

The frequency determining circuit 201 determines a frequency of the data received from the input circuit 202 based on a reference clock generated by the PLL circuit 205, and outputs a result of this determination to the selector circuit 206. This frequency determining circuit 201 has a feature that the frequency is determined from different data signals having a plurality of frequencies based on the number of counts of a signal having a pulse width shorter than a predetermined pulse width, which will be described in detail later.

The CDR circuit 204 extracts a clock from the data received from the input circuit 202, recovers the data, and outputs this data to the selector circuit 206.

The PLL circuit 205 generates the reference clock by phase synchronization control, and outputs this reference clock to the frequency determining circuit 201.

The selector circuit 206 takes the data received from the input circuit 202 and the data recovered by the CDR circuit 204 as its input, selects either one data based on the determination result from the frequency determining circuit 201, and outputs the data to the output circuit 203.

The output circuit 203 performs the waveform shaping for the data selected by the selector circuit 206 in a waveform equalizing unit, and then, transfers the data to the receiving-side integrated circuit 102. This output circuit 203 includes the waveform equalizing unit for performing the waveform shaping for the data and outputting the data.

<Configuration of Frequency Determining Circuit>

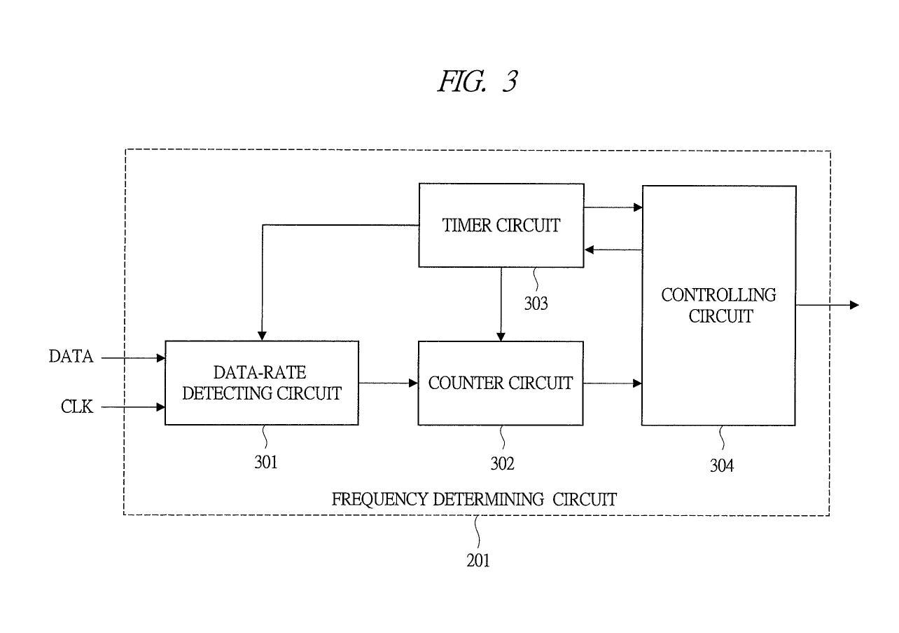

Next, with reference to FIG. 3, one configuration example of the above-described frequency determining circuit 201 is explained. FIG. 3 is a block diagram showing one configuration example of this frequency determining circuit 201.

The frequency determining circuit 201 shown in FIG. 3 includes: a data-rate detecting circuit 301; a counter circuit 302; a timer circuit 303; and a controlling circuit 304.

The data-rate detecting circuit 301 takes a data (DATA) from the input circuit 202 shown in FIG. 2 and a clock (CLOCK) from the PLL circuit 205 as its input, detects the signal having the pulse width shorter than the predetermined pulse width, and outputs a result of this detection to the counter circuit 302.

The counter circuit 302 counts a signal detected by this data-rate detecting circuit 301 from the detection result from the data-rate detecting circuit 301, and outs a result of this count to the controlling circuit 304.

The timer circuit 303 controls a section where the frequency is determined, and outputs a result of this control to the data-rate detecting circuit 301, the counter circuit 302, and the controlling circuit 304. By controlling the section where the data rate (frequency) is determined by this timer circuit 303, an unnecessary circuit can be stopped after the data-rate determination.

The controlling circuit 304 receives the counter result from the counter circuit 302 and the control result from the timer circuit 303, determines the frequency within the section, where the frequency is determined and which is controlled by the timer circuit 303, from the number of counts counted by the counter circuit 302 based on a relation between the frequency and the number of counts previously corresponded thereto, and outputs a result of this determination to the selector circuit 206 shown in FIG. 2. The determination result from this controlling circuit 304 is fed back also to the timer circuit 303. In this controlling circuit 304, in order to determine the frequency from the number of counts, it is previously set which frequency corresponds to the number of counts.

<Configuration and Operation of Data-Rate Detecting Circuit>

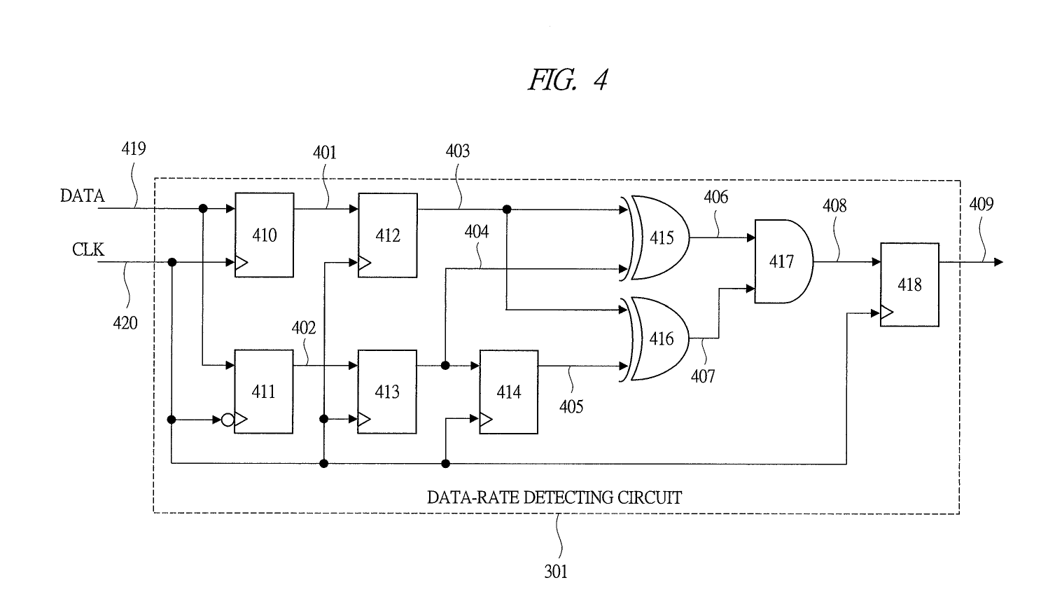

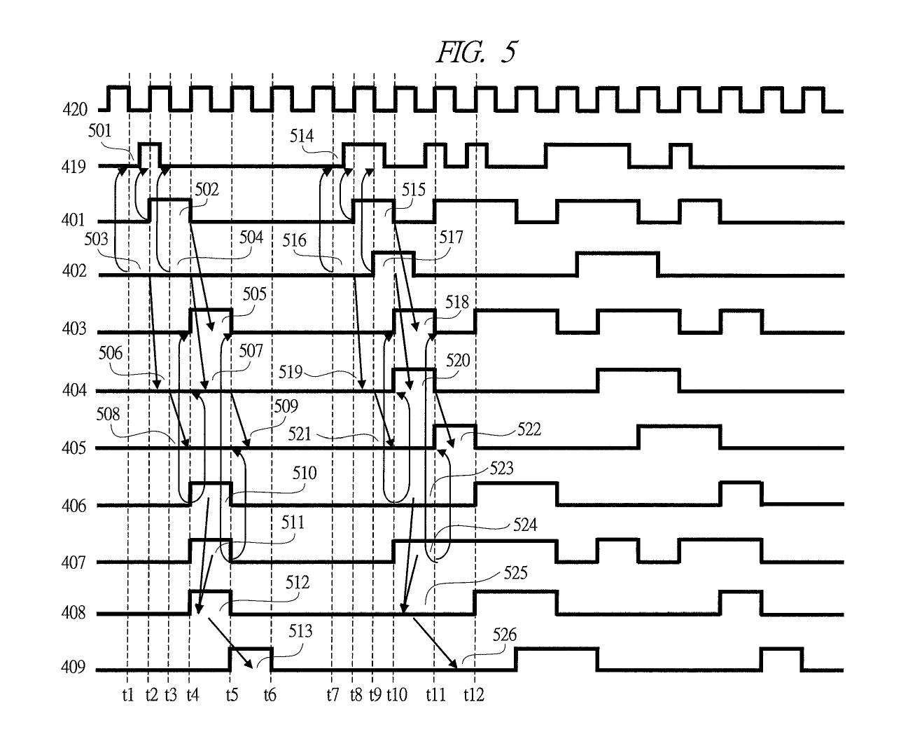

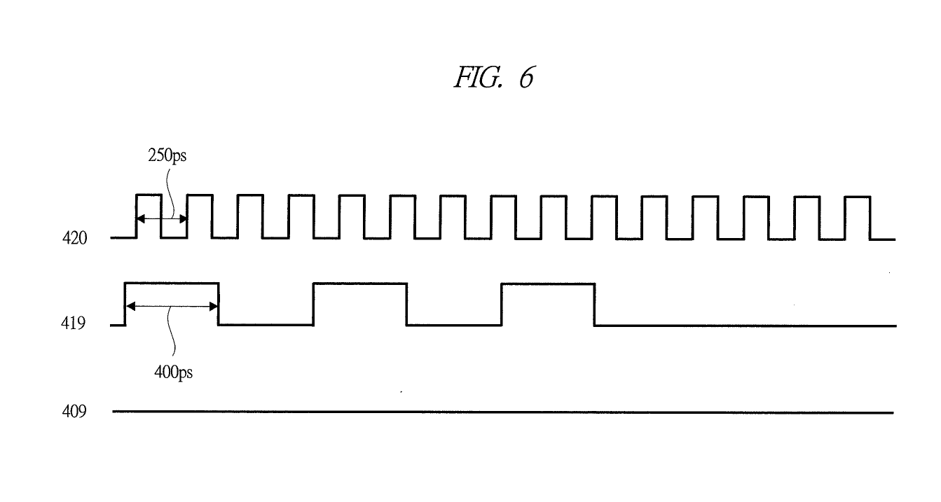

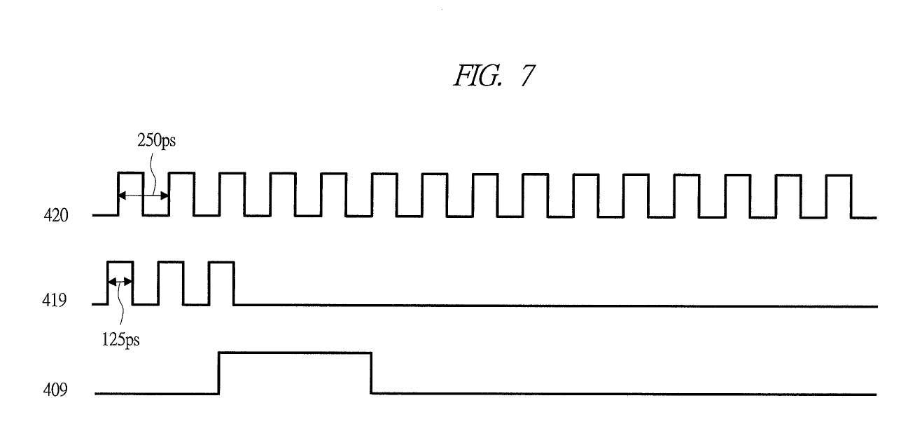

Next, with reference to FIGS. 4 to 7, one configuration and one operation examples of the above-described data-rate detecting circuit 301 is explained. FIG. 4 is a circuit diagram showing one configuration example of this data-rate detecting circuit 301. FIG. 5 is a signal waveform diagram for explaining one operation example of this data-rate detecting circuit 301. And, FIGS. 6 and 7 is signal waveform diagrams for explaining an operation in a case of a clock signal of 4.0 GHz and a data signal of 2.5 GHz and an operation in a case of a clock signal of 4.0 GHz and a data signal of 8.0 GHz, respectively.

The data-rate detecting circuit 301 shown in FIG. 4 is a circuit for detecting the pulse width shorter than the predetermined pulse width from data signals, and includes: FF (flip flop) circuits 410, 411, 412, 413, and 414; EXOR (exclusive OR) circuits 415 and 416; an AND (logical AND) circuit 417; and an FF circuit 418.

In FIGS. 4 and 5 which will be described later, a numerical symbol 420 indicates the clock signal (CLOCK), a numerical symbol 419 indicates the data signal (DATA), numerical symbols 401 to 409 indicate output signals, and numerical symbols 501 to 526 indicate signal patterns. Note that, for the numerical symbol of each signal of 420, 419, and 401 to 409, the same numerical symbol may be also added to a signal wire corresponding to a signal name for explanation.

In the operation in the case that the data-rate detecting circuit 301 detects the pulse width shorter than the predetermined pulse width as shown in FIG. 5, it is assumed that the predetermined pulse width is a pulse width of the clock signal. While the clock signal 420 is supplied to the FF circuits 410, 412, 413, 414, and 418, a signal obtained by inversing the clock signal 420 is supplied to the FF circuit 411 in order to detect the pulse width shorter than the predetermined pulse width (the pulse width of the clock signal).

For example, when the data signal 419 has a state of a signal pattern “010” (501), it has a shorter pulse width than the predetermined pulse width, and therefore, the detection is required. At this time, an output signal 401 of the FF circuit 410 has a pattern “010” (502), and an output signal 402 of the FF circuit 411 has a pattern “000” (503 and 504). After receiving the output signal 401, an output signal 403 of the FF circuit 412 has a pattern “010” (505). After receiving the output signal 402, an output signal 404 of the FF circuit 413 has a pattern “000” (506 and 507). After receiving the output signal 404, an output signal 405 of the FF circuit 414 has a pattern “000” (508 and 509). After receiving the output signals 403 and 404, an output signal 406 of the EXOR circuit 415 has a pattern “010” (510). After receiving the output signals 403 and 405, an output signal 407 of the EXOR circuit 416 has a pattern “010” (511). After receiving the output signals 406 and 407, an output signal 408 of the AND circuit 417 has a pattern “010” (512). After receiving the output signal 408, an output signal 409 of the FF circuit 418 has a pattern “010” (513).

On the other hand, when the data signal 419 has a state of a signal pattern “0110” (514), it has a longer pulse width than the predetermined pulse width, and therefore, the detection is not required. At this time, the output signal 401 of the FF circuit 410 has a pattern “010” (515), and the output signal 402 of the FF circuit 411 has a pattern “010” (516 and 517). After receiving the output signal 401, the output signal 403 of the FF circuit 412 has a pattern “010” (518). After receiving the output signal 402, the output signal 404 of the FF circuit 413 has a pattern “010” (519 and 520). After receiving the output signal 404, the output signal 405 of the FF circuit 414 has a pattern “010” (521 and 522). After receiving the output signals 403 and 404, the output signal 406 of the EXOR circuit 415 has a pattern “000” (523). After receiving the output signals 403 and 405, the output signal 407 of the EXOR circuit 416 has a pattern “011” (524). After receiving the output signals 406 and 407, the output signal 408 of the AND circuit 417 has a pattern “000” (525). After receiving the output signal 408, the output signal 409 of the FF circuit 418 has a pattern “000” (526).

In the above-described operations, when the data signal 419 has the state of the signal pattern “010” (501), the output signal 409 of the FF circuit 418 has a pattern “010” (513), and, when the data signal 419 has the state of the signal pattern “0110” (514), the output signal 409 of the FF circuit 418 has a pattern “000”. Therefore, only the pulse width shorter than the predetermined pulse width can be detected from the data signal 419 having the mixture of the short and long pulse widths.

The counter circuit 302 connected to the output side of this data-rate detecting circuit 301 counts the pulse of the output signal 409 supplied from the data-rate detecting circuit 301, and supplies the result to the controlling circuit 304.

FIG. 6 shows the operation in the case that the data-rate detecting circuit 301 shown in FIG. 4 receives a pattern “0101010” in the clock signal 420 of 4.0 GHz (250 ps) and the data signal 419 of 2.5 GHz. The shortest pulse width contained in this data signal 419 is 400 ps which is longer than the predetermined pulse width (1 cycle of the clock signal 420: 250 ps), and therefore, the pulse cannot be detected (as seen in the output signal 409). Therefore, the number of counts of the pulse at the counter circuit 302 is “0”.

FIG. 7 shows the operation in the case that the data-rate detecting circuit 301 shown in FIG. 4 receives a pattern “0101010” in the clock signal 420 of 4.0 GHz (250 ps) and the data signal 419 of 8.0 GHz. As different from the pattern of the data signal 419 shown in FIG. 6, the shortest pulse width is 125 ps which is shorter than the predetermined pulse width (1 cycle of the clock signal 420: 250 ps), and therefore, the pulse can be detected (as seen in the output signal 409). Therefore, the number of counts of the pulse at the counter circuit 302 is “3”.

For example, if the pulse of the data signal is counted without using the present invention, the numbers of counts of both of the data signals are “3”, and therefore, their frequencies cannot be differentiated from each other. That is, by using the present invention, the numbers of counts of the pulses are differentiated depending on the data rate, and, as a result, the frequency can be detected.

The timer circuit 303 connected to this data-rate detecting circuit 301 controls the section where the data rate is determined. By controlling the section where the data rate is determined, an unnecessary circuit can be stopped after the data-rate determination, and therefore, excessive power consumption can be suppressed.

Also, the controlling circuit 304 connected to the counter circuit 302 and the timer circuit 303 receives the result counted by the counter circuit 302, determines the frequency from the number of counts, and outputs the result. For this determination, it is required to previously set which frequency corresponds to the number of counts.

### Effect of First Embodiment

According to the frequency determining circuit 201 configuring the transmission mechanism performing the data transfer of the data-transfer integrated circuit 103 included in the data-transfer system according to the first embodiment as described above, the frequency of the data signal having the mixture of the short and long pulse widths can be determined by providing the circuit which acquires the different data signals having the plurality of frequencies and determines the frequency based on the number of counts of the signal having the pulse width shorter than the predetermined pulse width, more specifically, by providing the data-rate detecting circuit 301, the counter circuit 302, the timer circuit 303, and the controlling circuit 304. And, according to the semiconductor device in which the data-transfer integrated circuit 103 including this frequency determining circuit 201 as an output buffer unit is formed, the operation rate can be judged from the input signal, and output characteristics can be changed in accordance with the result.

### Second Embodiment

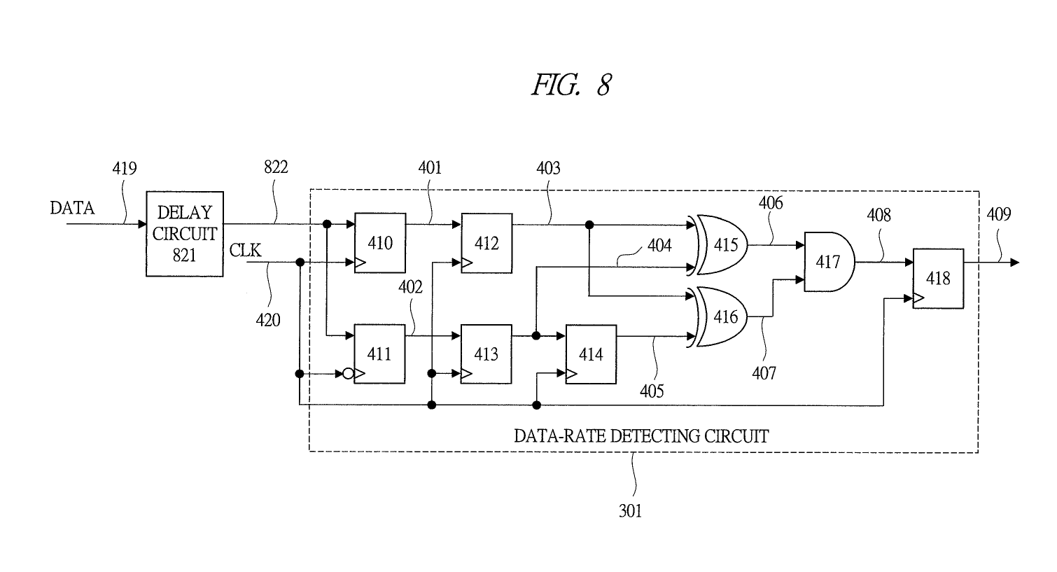

A second embodiment of the present invention is explained with reference to FIGS. 8 to 11.

In the present second embodiment, the configuration (FIG. 1) of the data-transfer system including the plurality of integrated circuits performing the data transfer, the configuration (FIG. 2) of the transmission mechanism performing the data transfer of the data-transfer integrated circuit included in this data-transfer system, and the configuration (FIG. 3) of the frequency determining circuit configuring the transmission mechanism performing the data transfer of this data-transfer integrated circuit are the same as those in the above-described first embodiment, and therefore, their descriptions are omitted here.

The present second embodiment is different from the above-described first embodiment (FIG. 4) in the configuration and the operation of the part of the data-rate detecting circuit configuring the frequency determining circuit, and a different point of the part of the data-rate detecting circuit is mainly explained hereinafter.

<Configuration and Operation of Part of Data-Rate Detecting Circuit>

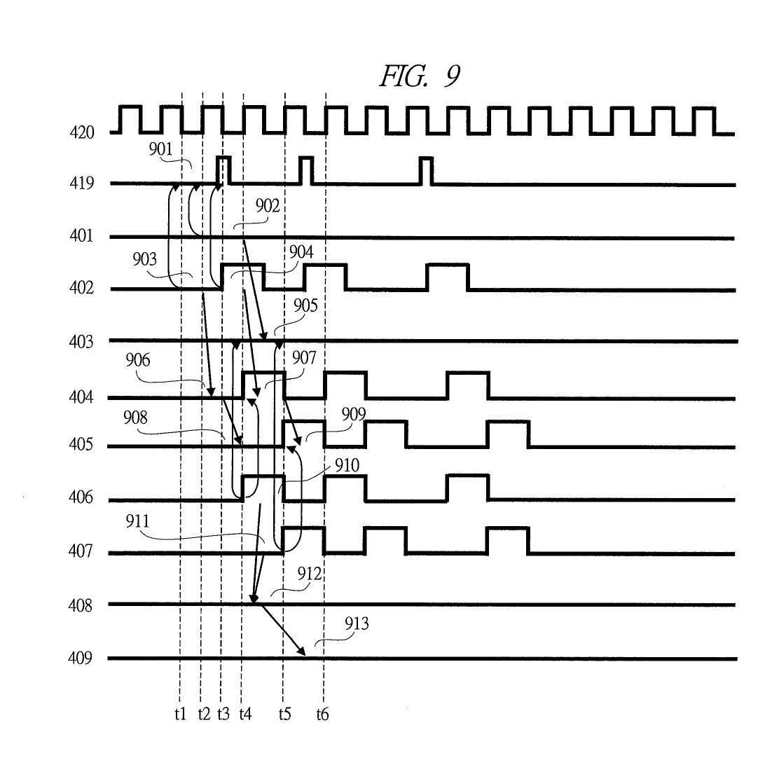

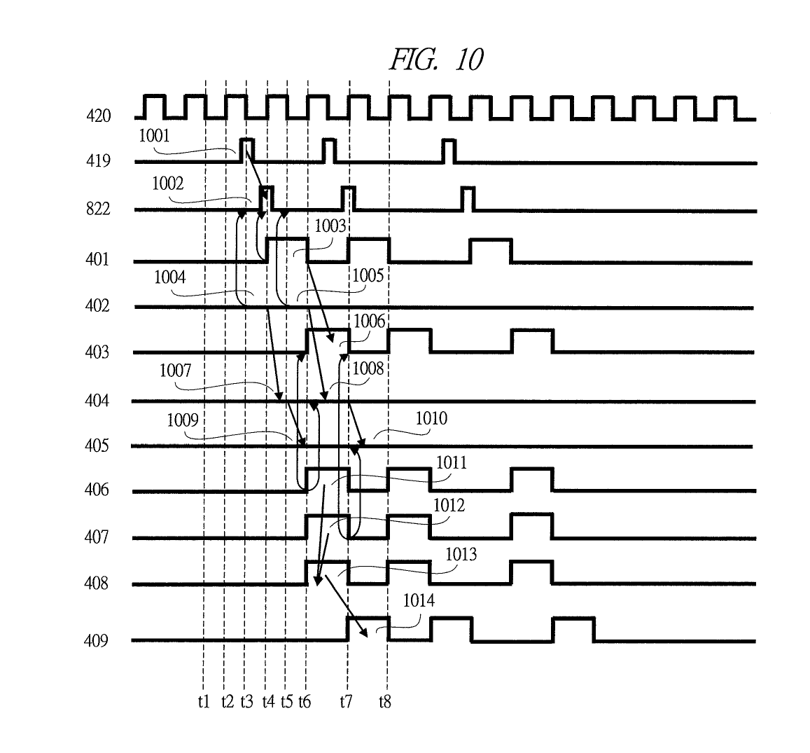

With reference to FIGS. 8 to 11, one configuration and one operation examples of the part of the data-rate detecting circuit 301 are explained. FIG. 8 is a circuit diagram showing one configuration example of the part of this data-rate detecting circuit 301. FIG. 9 is a signal waveform diagram for explaining one operation example (in a case without a delay circuit 821) of the part of the data-rate detecting circuit 301 for comparison. FIG. 10 is a signal waveform diagram for explaining one operation example (in a case with the delay circuit 821) of the part of the data-rate detecting circuit 301.

The part of the data-rate detecting circuit 301 shown in FIG. 8 includes the delay circuit 821 connected to a previous stage of the data signal input of this data-rate detecting circuit 301 in addition to the data-rate detecting circuit 301 shown in FIG. 4.

In FIG. 8 and FIGS. 9 and 10 which will be described later, a numerical symbol 420 indicates a clock signal (CLK), a numerical symbol 419 indicates a data signal (DATA), a numerical symbol 822 indicates a delayed data signal, numerical symbols 401 to 409 indicate output signals, numerical symbols 901 to 913 indicate signal patterns, and numerical symbols 1001 to 1014 indicate signal patterns.

FIG. 9 is a diagram showing an operation for describing a reason for requirement of the delay circuit 821. When the data-rate detecting circuit 301 shown in FIG. 4 receives a pattern (901) of the data signal 419 shown in FIG. 9, a pulse width shorter than a predetermined pulse width is contained in the data signal. However, as shown in an output signal 409 (913) obtained through output signals 401 (902) to 408 (912), the pulse width shorter than the predetermined pulse width cannot be detected, and therefore, the frequency cannot be correctly determined.

On the other hand, FIG. 10 is a diagram showing an operation in a case that the configuration of the data-rate detecting circuit 301 with the delay circuit 821 shown in FIG. 8 receives the data signal 419 shown in FIG. 9. When the data-rate detecting circuit 301 shown in FIG. 8 receives a pattern (1001) of the data signal 419 shown in FIG. 10, the pulse width shorter than the predetermined pulse width can be detected since the data signal 419 is delayed by the delay circuit 821 (output signal 822 (1002)) as shown in the output signal 409 (1014) obtained through output signals 401 (1003) to 408 (1013), and therefore, the frequency can be correctly determined.

### Effect of Second Embodiment

Also in the present second embodiment described above, the same effect as that of the above-described first embodiment can be obtained, and besides, the frequency of the data signal having the mixture of the short and long pulse widths can be correctly determined since the pulse width much shorter than the predetermined pulse width can be detected by the configuration of the data-rate detecting circuit 301 with the delay circuit 821.

### Modification Example of Second Embodiment (or First Embodiment)

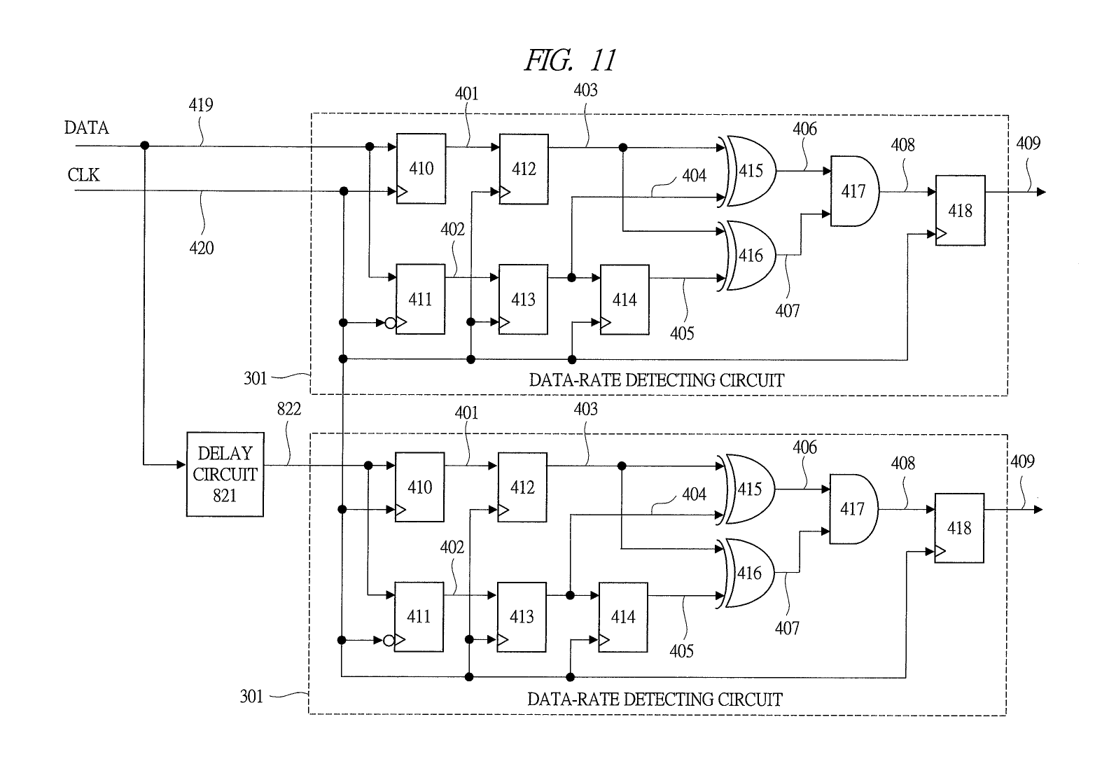

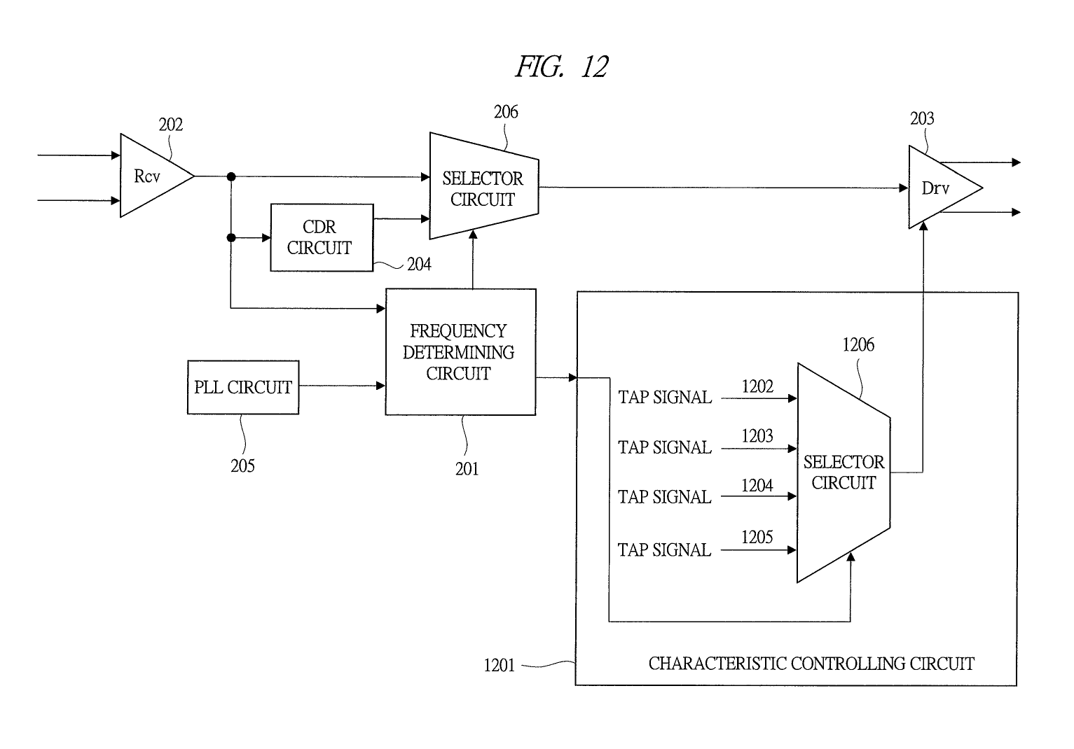

FIG. 11 is a circuit diagram showing an example that the part of the data-rate detecting circuit 301 is configured by two stages of the data-rate detecting circuits 301 with the delay circuit 821 as a modification example of the second embodiment (or the first embodiment).

In the part of the data-rate detecting circuit 301 shown in FIG. 11, the data-rate detecting circuit 301 (on an upper side in FIG. 11) which directly receives the data signal (DATA) and the data-rate detecting circuit 301 (on a lower side in FIG. 11) which receives the signal obtained after the delay via the delay circuit 821 are combined to be connected in parallel so as to detect each pulse, so that the pulse width shorter than the predetermined pulse width can be detected regardless of the pattern. Therefore, in this modification example of the second embodiment (or first embodiment), the frequency of the data signal further having the mixture of the short and long pulse widths than that of the second embodiment (FIG. 8) can be correctly determined.

### Third Embodiment

A third embodiment of the present invention is explained with reference to FIG. 12.

In the present third embodiment, the configuration (FIG. 1) of the data-transfer system including the plurality of integrated circuits performing the data transfer is the same as that in the above-described first embodiment, and therefore, its description is omitted here.

The present third embodiment is different from the above-described first embodiment (FIG. 2) and second embodiment in the configuration of the transmission mechanism performing the data transfer of the data-transfer integrated circuit included in the data-transfer system, and a different point in the configuration of the transmission mechanism performing the data transfer of the data-transfer integrated circuit is mainly explained hereinafter.

Note that the same circuit as those of the above-described first and second embodiments can be used for the frequency determining circuit (FIG. 3) configuring the transmission mechanism performing the data transfer of this data-transfer integrated circuit, the data-rate detecting circuit (FIGS. 4 and 8) configuring this frequency determining circuit, and others.

<Configuration of Transmission Mechanism performing Data Transfer of Data-Transfer Integrated Circuit>

With reference to FIG. 12, one configuration example of the transmission mechanism performing the data transfer of the data-transfer integrated circuit is explained. FIG. 12 is a block diagram showing one configuration example of the transmission mechanism performing the data transfer of this data-transfer integrated circuit.

The configuration of the transmission mechanism performing the data transfer of the data-transfer integrated circuit shown in FIG. 12 is different from the configuration of the transmission mechanism performing the data transfer of the data-transfer integrated circuit shown in FIG. 2 in a point that a characteristic controlling circuit 1201 connected between the frequency determining circuit 201 and the output circuit 203 is provided.

This characteristic controlling circuit 1201 is a circuit which includes a selector circuit 1206 for selecting a TAP coefficient from any one of TAP signals 1202, 1203, 1204, and 1205, and can switch the TAP coefficient to any one of the TAP signals 1202, 1203, 1204, and 1205 in this selector circuit 1206 in accordance with a result of the frequency determination outputted from the frequency determining circuit 201. For example, as one example of the TAP signals 1202, 1203, 1204, and 1205 for this TAP coefficient, set signals such as LL level, LH level, HL level, and HH level in ascending order from low to high can be considered.

A result of the switching which is outputted from this characteristic controlling circuit 1201 is inputted to the output circuit 203, and the waveform equalizing unit of this output circuit 203 is controlled based on the switched TAP coefficient. By switching the TAP coefficient, such an output emphasis value as canceling the frequency characteristics of the transmission channel can be set. That is, the characteristics of the transmission mechanism can be controlled by this characteristic controlling circuit 1201.

### Effect of Third Embodiment

Also in the present third embodiment described above, the same effect as those of the above-described first and second embodiments can be obtained, and besides, the characteristics of the transmission mechanism can be controlled since the frequency characteristics of the transmission channel can be cancelled by switching the TAP coefficient with using the characteristic controlling circuit 1201. And, according to the semiconductor device in which the data-transfer integrated circuit including this characteristic controlling circuit 1201 as an output buffer unit is formed, the operation rate can be judged from the input signal, and the TAP setting in the waveform equalizing unit can be dynamically changed in accordance with the result.

### Fourth Embodiment

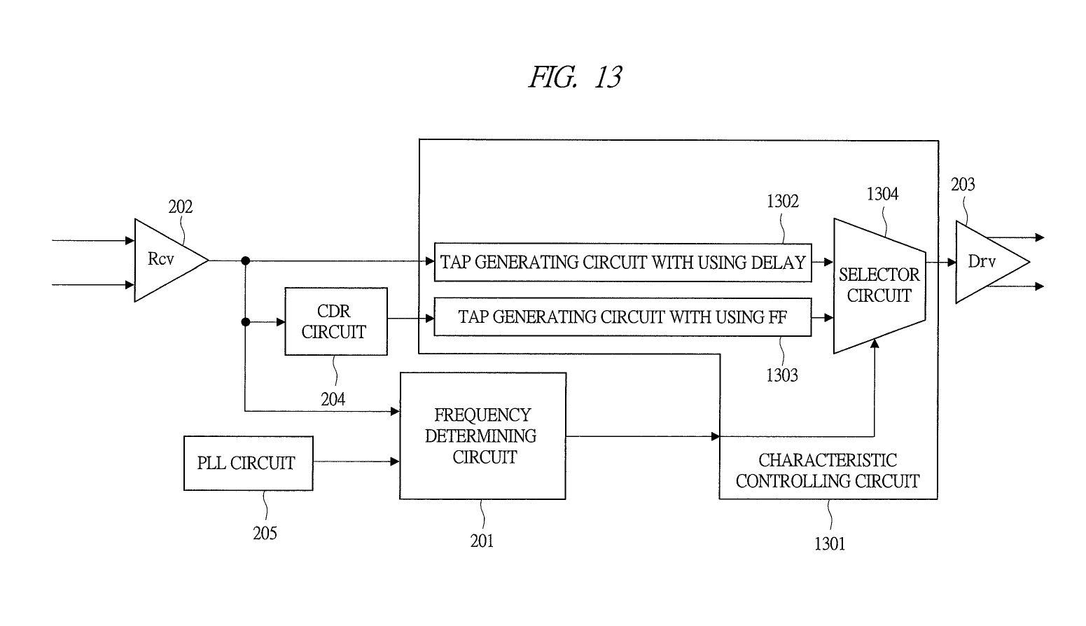

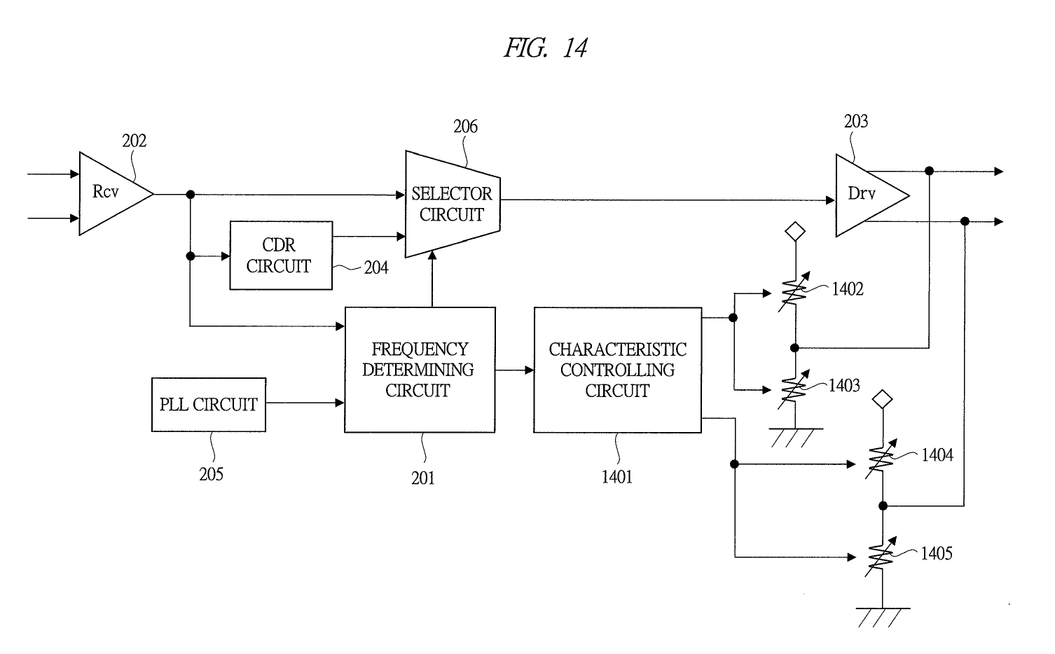

A fourth embodiment of the present invention is explained with reference to FIG. 13.

Similarly to the above-described third embodiment, the present fourth embodiment is different from the above-described first embodiment (FIG. 2), second embodiment, and third embodiment (FIG. 12) in the configuration of the transmission mechanism performing the data transfer of the data-transfer integrated circuit included in the data-transfer system, and a different point in the configuration of the transmission mechanism performing the data transfer of the data-transfer integrated circuit is mainly explained hereinafter.

<Configuration of Transmission Mechanism performing Data Transfer of Data-Transfer Integrated Circuit>

With reference to FIG. 13, one configuration example of the transmission mechanism performing the data transfer of the data-transfer integrated circuit is explained. FIG. 13 is a block diagram showing one configuration example of the transmission mechanism performing the data transfer of this data-transfer integrated circuit.

The configuration of the transmission mechanism performing the data transfer of the data-transfer integrated circuit shown in FIG. 13 is different from the configuration of the transmission mechanism performing the data transfer of the data-transfer integrated circuit shown in FIG. 12 in a point that a characteristic controlling circuit 1301 selects not the TAP coefficient but a method for generating the TAP.

This characteristic controlling circuit 1301 includes: a TAP generating circuit 1302 with using delay; a TAP generating circuit 1303 with using FF; and a selector circuit 1304 for selecting either of the TAP generating circuits. The TAP generating circuit 1302 with using delay is directly connected to the input circuit 202, and the TAP generating circuit 1303 with using FF is connected to the CDR circuit 204.

This characteristic controlling circuit 1301 is a circuit for generating emphasis by supplying a signal for selecting the TAP generating circuit 1302 with using delay or the TAP generating circuit 1303 with using FF to the selector circuit 1304 in accordance with the result of the frequency determination outputted from the frequency determining circuit 201 to select either the TAP generating circuit 1302 with using delay or the TAP generating circuit 1303 with using FF. That is, by this characteristic controlling circuit 1301, the characteristics of the transmission mechanism can be controlled.

For example, in a normal operation, in order to perform retiming of the input signal with using the CDR circuit, a waveform for the TAP is generated by the TAP generating circuit 1303 with using FF. As this TAP generating circuit 1303 with using FF, a 4 TAP method or others is considered as one example, in which four FFs are connected in cascade connection to provide a PRE signal (−1 cyc), a MAIN signal, a POST 1 signal (+1 cyc), and a POST 2 signal (+2 cyc). On the other hand, in a low-speed operation, a circuit which uses the clock such as the CDR circuit is stopped, and the waveform is generated by the TAP generating circuit 1302 with using delay. As this TAP generating circuit 1302 with using delay, a 2 TAP method or others is considered as one example, in which one delay is used to provide the MAIN signal and the POST 1 signal (+1 cyc).

### Effect of Fourth Embodiment

Also in the present fourth embodiment described above, the same effect as those of the above-described first and second embodiments can be obtained, and besides, the characteristics of the transmission mechanism can be controlled similarly to the above-described third embodiment since the frequency characteristics of the transmission channel can be cancelled by switching the method for generating the TAP by the characteristic controlling circuit 1301. And, according to the semiconductor device in which the data-transfer integrated circuit including this characteristic controlling circuit 1301 as an output buffer unit is formed, the operation rate is judged from the input signal, and the method for generating the TAP can be dynamically changed in accordance with the result.

### Fifth Embodiment

A fifth embodiment of the present invention is explained with reference to FIG. 14.

Similarly to the above-described third and fourth embodiments, the present fifth embodiment is different from the above-described first embodiment (FIG. 2), second embodiment, third embodiment (FIG. 12), and fourth embodiment (FIG. 13) in the configuration of the transmission mechanism performing the data transfer of the data-transfer integrated circuit included in the data-transfer system, and a different point in the configuration of the transmission mechanism performing the data transfer of the data-transfer integrated circuit is mainly explained hereinafter.

<Configuration of Transmission Mechanism performing Data Transfer of Data-Transfer Integrated Circuit>

With reference to FIG. 14, one configuration example of the transmission mechanism performing the data transfer of the data-transfer integrated circuit is explained. FIG. 14 is a block diagram showing one configuration example of the transmission mechanism performing the data transfer of this data-transfer integrated circuit.

The configuration of the transmission mechanism performing the data transfer of the data-transfer integrated circuit shown in FIG. 14 is different from the configuration of the transmission mechanism performing the data transfer of the data-transfer integrated circuit shown in FIG. 12 in a point that an output level in a non operation is switched.

In the configuration of the transmission mechanism performing the data transfer of this data-transfer integrated circuit, a characteristic controlling circuit 1401 is connected to the frequency determining circuit 201, and variable resistors 1402, 1403 (a P pole of a differential signal), 1404, and 1405 (an N pole of the differential signal) which are connected in series between a power supply and ground are connected to an output of the output circuit 203. These variable resistors 1402, 1403, 1404, and 1405 are controlled by the output of the frequency determining circuit 201.

The characteristic controlling circuit 1401 shown in FIG. 14 is a circuit which can automatically support a plurality of standards by outputting a signal for varying the output level of the output circuit 203 by the variable resistors 1402, 1403, 1404, and 1405 in accordance with the result of the frequency determination outputted from the frequency determining circuit 201. That is, as different from the above-described third and fourth embodiments, the present fifth embodiment can achieve not the improvement of the characteristics in accordance with the transfer rate but the automatic support for the plurality of standards such as having different transfer rates.

For example, in a case of supporting different standards as PCI-Express and 10 G-Ether/FC, one example is considered as follows. In the mode of the PCI-Express, it is set that the output level in the non operation is an intermediate level, and the output level can be also changed so as to fix to H or L. If the frequency determining circuit recognizes the transfer rate of the 10 G-Ether/FC, the output level in the non operation is changed to H or L.

### Effect of Fifth Embodiment

Also in the present fifth embodiment described above, the same effect as those of the above-described first and second embodiments can be obtained, and besides, the plurality of standards can be automatically supported since the output level in the non operation can be switched by varying the output level of the output circuit 203 by the configuration of the characteristic controlling circuit 1401 with the variable resistors 1402, 1403, 1404, and 1405. And, according to the semiconductor device in which the data-transfer integrated circuit including the configuration of this characteristic controlling circuit 1401 with the variable resistors 1402, 1403, 1404, and 1405 as an output buffer unit is formed, the operation rate is judged from the input signal, and the output level in the non operation can be dynamically changed in accordance with the result.

In the foregoing, the invention made by the inventors has been concretely described based on the embodiments. However, it is needless to say that the present invention is not limited to the foregoing embodiments and various modifications and alterations can be made within the scope of the present invention.

The present invention can be used for a frequency determining circuit for determining a frequency from different data signals having a plurality of frequencies and for a semiconductor device including this frequency determining circuit.

What is claimed is:

1. A frequency determining circuit for determining a frequency from different data signals having a plurality of frequencies,
the frequency determining circuit including a circuit which acquires the different data signals having the plurality of frequencies and determines the frequency based on the number of counts of a signal having a pulse width shorter than a predetermined pulse width.

2. The frequency determining circuit according to claim 1, wherein
the frequency determining circuit includes:
a data-rate detecting circuit for detecting the signal having the pulse width shorter than the predetermined pulse width;
a counter circuit for counting a signal detected by the data-rate detecting circuit;
a timer circuit for controlling a section where the frequency is determined; and
a controlling circuit for determining the frequency from the number of counts counted by the counter circuit, within the section where the frequency is determined, which is controlled by the timer circuit, based on a relation between the frequency and the number of counts which is previously corresponded thereto.

3. The frequency determining circuit according to claim 2, wherein
the frequency determining circuit includes a delay circuit for delaying the acquired data signal at a previous stage of the data-rate detecting circuit.

4. The frequency determining circuit according to claim 3, wherein
the frequency determining circuit is configured so that a configuration in which the delay circuit is connected to the previous stage of the data-rate detecting circuit and a configuration including the data-rate detecting circuit are connected in parallel to each other.

5. A semiconductor device including a frequency determining circuit for determining a frequency from different data signals having a plurality of frequencies,
the frequency determining circuit including a circuit which acquires the different data signals having the plurality of frequencies and determines the frequency based on the number of counts of the signal having the pulse width shorter than the predetermined pulse width.

6. The semiconductor device according to claim 5, wherein
the frequency determining circuit includes:
a data-rate detecting circuit for detecting the signal having the pulse width shorter than the predetermined pulse width;
a counter circuit for counting a signal detected by the data-rate detecting circuit;
a timer circuit for controlling a section where the frequency is determined; and
a controlling circuit for determining the frequency from the number of counts counted by the counter circuit, within the section where the frequency is determined, which is controlled by the timer circuit, based on a relation between the frequency and the number of counts which is previously corresponded thereto.

7. The semiconductor device according to claim 6, wherein
a delay circuit for delaying the acquired data signal is connected to a previous stage of the data-rate detecting circuit.

8. The semiconductor device according to claim 7, wherein
the frequency determining circuit is configured so that a configuration in which the delay circuit is connected to the previous stage of the data-rate detecting circuit and a configuration including the data-rate detecting circuit are connected in parallel to each other.

9. The semiconductor device according to claim 5, wherein
the frequency determining circuit further includes a characteristic controlling circuit for controlling characteristics of a transmission mechanism based on a determination result of the frequency determining circuit.

10. The semiconductor device according to claim 9, wherein
the characteristic controlling circuit includes a circuit which is connected to an output circuit including a waveform equalizing unit for waveform-shaping the data signal and outputting it and which selects a TAP coefficient of the waveform equalizing unit.

11. The semiconductor device according to claim 9, wherein
the characteristic controlling circuit includes a circuit which is connected to an output circuit including a waveform equalizing unit for waveform-shaping the data signal and outputting it and which selects a method for generating TAP of the waveform equalizing unit.

12. The semiconductor device according to claim 9, wherein
the characteristic controlling circuit is connected via a variable resistor to an output circuit including a waveform equalizing unit for waveform-shaping the data signal and outputting it, and controls the variable resistor so as to vary an output level of the output circuit.
